(19) United States
(12) Patent Application Publication
(10) Pub. No.: US 2006/0090789 A1
(43) Pub. Date: May 4, 2006

(54) Floating support structure for a solar panel array

(76) Inventor: Daniel S. Thompson, San Rafael, CA (US)

Correspondence Address: JOHNSON & STAINBROOK, LLP, 3558 ROUND BARN BLVD., SUITE 203, SANTA ROSA, CA, 95403, US

(21) Appl. No.: 11/264,285

(22) Filed: Oct. 31, 2005

Related U.S. Application Data
(60) Provisional application No. 60/623,328, filed on Oct. 29, 2004.

(51) Int. Cl. H01L 25/00

(52) U.S. Cl. 136/246; 136/251; 136/244

(57) ABSTRACT

A floating support structure for a solar panel array having flotation elements and a tubular support structure disposed above the flotation elements for adjustably mounting at least one solar collector panel. Connector tubes and connector rings are provided near the base of the support structure for joining adjoining floating support structures.

### CROSS REFERENCE To RELATED APPLICATIONS

The present application claims the benefit of the filing date of U.S. Provisional Patent Application Ser. No. 60/623,328, filed Oct. 29, 2004 (Oct. 29, 2004).

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

The present invention relates generally to photovoltaic power systems, and more particularly to support structures for solar photovoltaic collector panels, and still more particularly to a floating support structure for a solar panel array.

### BACKGROUND INFORMATION AND DISCUSSION OF RELATED ART

With a few exceptions, solar panel support structures are almost invariably adapted for installation of a solar panel on the ground or a rooftop. Notable exceptions include support frameworks for mounting solar panels on vehicles and boats, and more exotic uses may even call for an installation with no support framework, such as with small glue on/screw on thin solar panels for use in extreme environments.

Rooftop solar arrays require the modification of the rooftop structure, can be dangerous and difficult to work on, and provide only a limited footprint. On the other hand, land is increasingly expensive and may be exploited for a number of purposes other than solar array installation. Additionally, the amount of land required for a solar array that generates a significant amount of electrical power can be considerable. Accordingly, because bodies of water comprise two thirds of the surface area of the earth, and because many large areas of water surfaces have no critical uses that cannot be provided for elsewhere, it may be desirable to dedicate large surface areas of water to the collection of solar energy and the conversion of solar energy to electricity.

There is as yet no known art showing suitable flotation elements for installing and deploying a large solar array on a body of water.

### BRIEF SUMMARY OF THE INVENTION

The present invention is a floating support structure for solar collectors. The invention provides for water-mounting of an array of solar panels with no ground mounts, roof mounts, minimal materials and minimal labor in installation. In addition, the invention includes a pre-angled mounting component for tilting the array (herein after referred to as “framework”) at a desired angle for best collection of solar radiation (e.g., 20 degrees). It also provides for transverse angling of the entire array on water, which incorporates posts mounted vertical and separately.

The inventive apparatus comprises a number of lightweight elongate tube elements that can be assembled at the time of manufacture. Alternatively, because the tubular elements are easily stacked and compactly stored, the assembly elements can be transported to an installation site and assembled at the site.

It is therefore an object of the present invention to provide a new and improved modular floating support structure for a solar panel.

It is another object of the present invention to provide a new and improved floating support structure for a solar panel array that may be connected to other like modules to form an array.

A further object or feature of the present invention is a new and improved floating structure for a solar panel array that permits solar panels to be tilted for optimum solar energy collection while afloat.

An even further object of the present invention is to provide a novel floating structure for a solar panel array that is lightweight and easily transported to and assembled at or near an installation site.

There has thus been broadly outlined the more important features of the invention in order that the detailed description that follows may be better understood, and in order that the present contribution to the art may be better appreciated. Additional objects, advantages and novel features of the invention will be set forth in part in the description as follows, and in part will become apparent to those skilled in the art upon examination of the following. Furthermore, such objects, advantages and features may be learned by practice of the invention, or may be realized and attained by means of the instrumentalities and combinations particularly pointed out in the appended claims.

Still other objects and advantages of the present invention will become readily apparent to those skilled in this art from the following detailed description, which shows and describes only the preferred embodiments of the invention, simply by way of illustration of the best mode now contemplated of carrying out the invention. As will be realized, the invention is capable of modification in various obvious respects without departing from the invention. Accordingly, the drawings and description of the preferred embodiment are to be regarded as illustrative in nature, and not as restrictive.

### BRIEF DESCRIPTION OF THE SEVERAL VIEWS OF THE DRAWINGS

The invention will be better understood and objects other than those set forth above will become apparent when consideration is given to the following detailed description thereof. Such description makes reference to the annexed drawings wherein:

FIG. 1 is a perspective view of the modular floating support structure for a solar panel array of the present invention;

FIG. 2 is a front view in elevation thereof;

FIG. 3 is a rear view in elevation thereof;

FIG. 4 is a side view in elevation thereof;

FIG. 5 is a side view in elevation of a plurality of the modular floating support structures showing how such structures may be connected and deployed in a floating solar panel array;

FIG. 5A is a perspective view showing a bar with carabineers disposed at its ends as used to connect adjacent modules at their respective sides; and

FIG. 6 is a top view showing a plurality of the inventive modular support structures connected in an array.

### DETAILED DESCRIPTION OF THE INVENTION

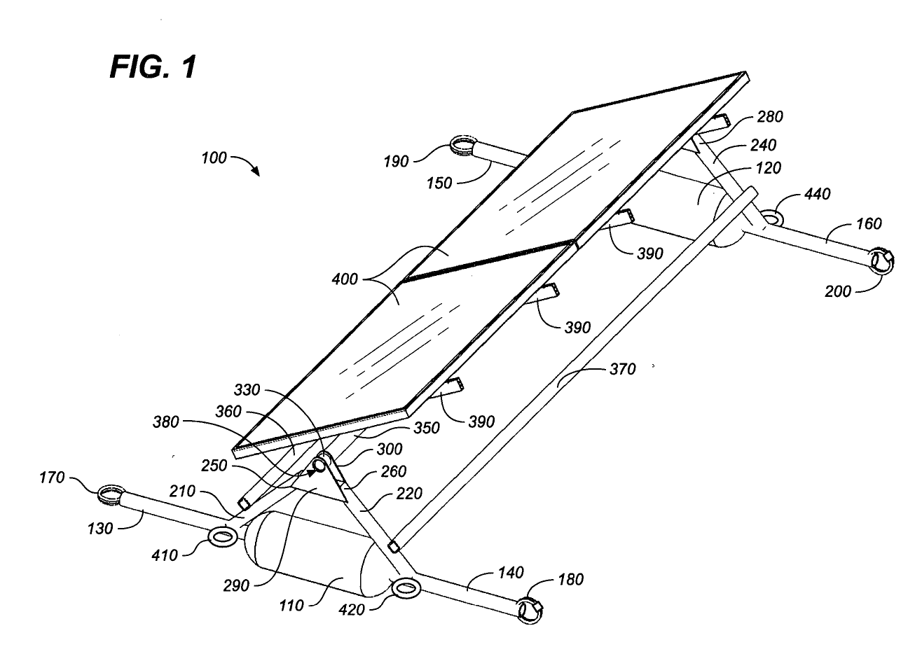

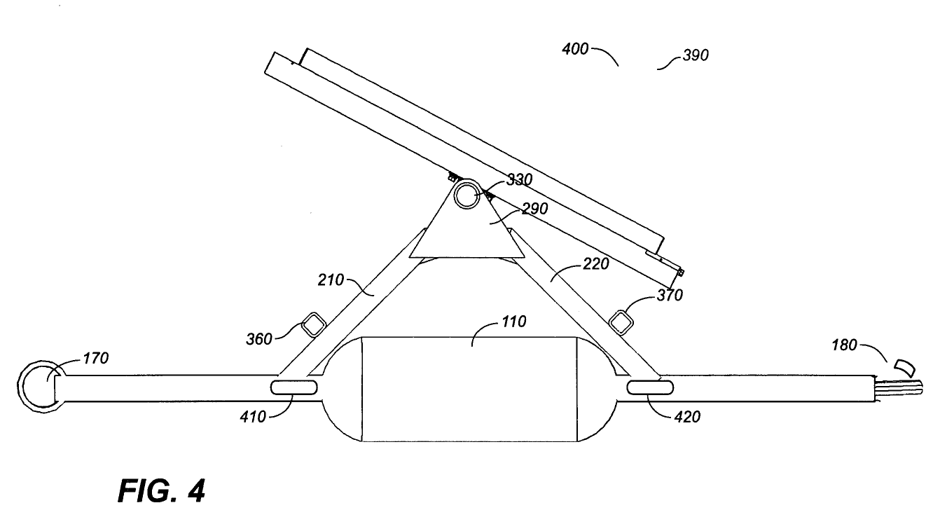

Referring to FIGS. 1 through 6, wherein like reference numerals refer to like components in the various views, there is illustrated therein a new and improved modular floating support structure for a solar panel array, generally denominated 100 herein.

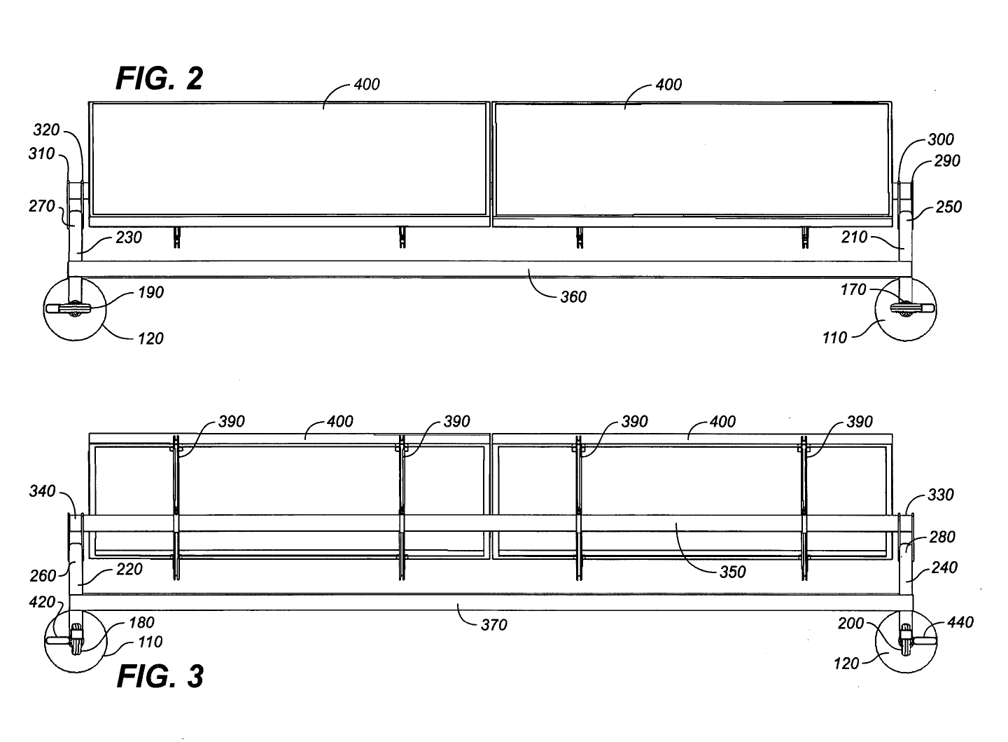

FIG. 1 is a perspective view of the modular support structure, while FIGS. 2, 3, and 4 are, respectively, front, back, and side elevation views of the module of FIG. 1. Collectively, these views show that this basic modular component of a floating array comprises first and second elongate flotation elements 110, 120, preferably substantially cylindrical pontoons, each having connector tubes 130, 140, and 150, 160, extending longitudinally from each respective end. Preferably the connector tubes are round in cross section, and their respective distal ends include front and rear connector rings, 170, 190, and 180, 200, respectively. The front connector rings 170, 190 are disposed generally perpendicular to the rear connector rings 180, 200, and either the front or rear connector rings or both are provided with a hinge element that allows the rings to capture rings in an adjacent module, in the manner of a tubular carabineer. Effectively, then, one set of connector rings comprises rigid connector rings, while the complementary set of connector rings comprises carabineers that attach to the rigid connector rings. As with carabineers, it is well known to provide locking means to prevent the hinge element in the carabineer from inadvertently opening. Such structures considered obvious design choices and are contemplated within the scope of the present invention.

Straddling the ends of each flotation element are upright supports, 210, 220, and 230, 240, glued, welded, bolted, or otherwise affixed at their lower ends to the connector tubes extending longitudinally from the flotation element, or to the flotation elements themselves, and which angle inwardly toward one another to join or substantially join at their respective upper ends, 250, 260, and 270, 280. The angled uprights are preferably fabricated from square tubing. The manufacturing means may be adapted to the anticipated installation, as welding or gluing may provide a sturdier structure with greater durability, but assembly with nuts and bolts may allow for easy transportation for assembly at an installation site.

Spaced apart parallel plates 290/300, and 310/320, may be glued, welded, bolted, or otherwise rigidly affixed to the opposite sides of the uprights at or near the junction of the upper ends of the angled uprights to provide increased structural integrity. Additionally, the plates may be provided with holes in which to journal the ends 330, 340 of a rotatable panel frame mounting tube 350. Two or more additional transverse tubes 360, 370, may be disposed between, and connected to, the angled uprights, so as to make a generally rigid framework structure. Adjustment/locking means 380 may be provided to permit selective release, rotation, and re-locking of the mounting tube. A number of suitable devices can be provided, including hole and nipple assemblies, pawl and ratchet, locking collar and ring, and the like. The drawings show a pawl and ratchet assembly as an illustrative mechanism.

The rotatable panel frame mounting tube can be provided with a plurality of support rails 390 on which to fasten and secure one or more solar photovoltaic panels 400.

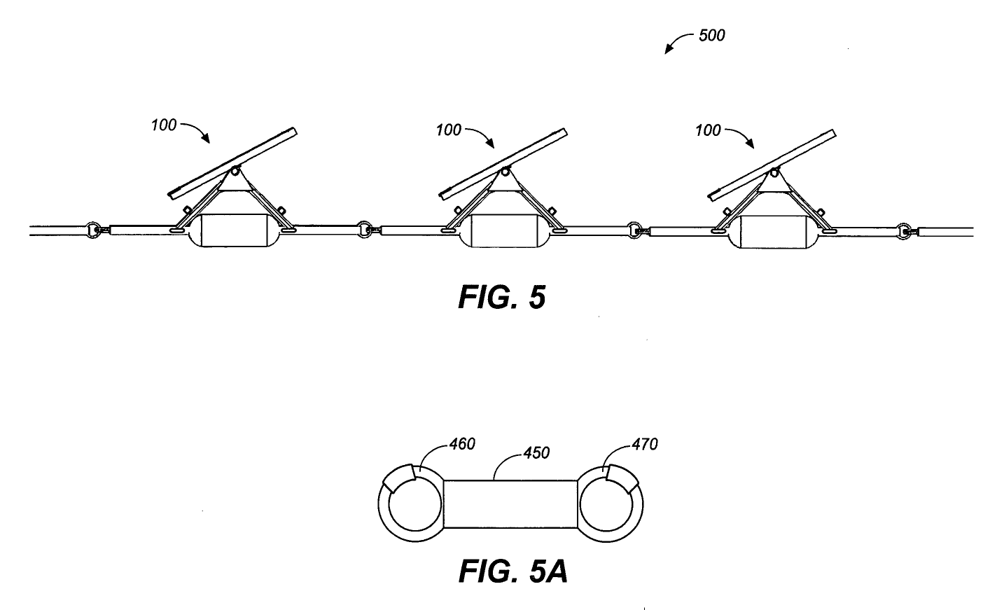

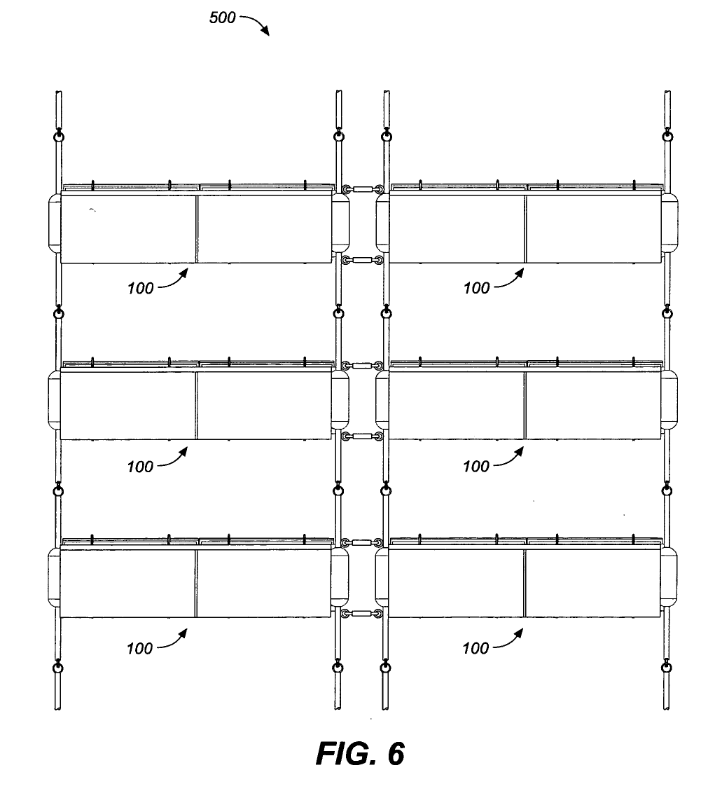

The module framework may also be provided with side connector rings 410, 420, 430, 440, disposed along each of the sides of the support structure. While only one side connector ring need be provided for each side of the support structure, and may be positioned anywhere along the length of the flotation element or connector tubes, it is preferable to have two side connector rings, one each extending outwardly from a each front and rear connector tube. Referring now to FIG. 5A, side connector bars 450, having hinged carabineers connector rings 460, 470 at each end may then be provided as means for joining the sides of adjacent support modules in a floating solar panel array 500 (see FIGS. 5 and 6). As an alternative, a side connector bar may be provided for installation between the front or rear connector ring of an adjoining support structure, so that no additional rings need be provided to ensure that the spacing between floating modules is fixed.

FIGS. 5 and 6 show the modules of FIGS. 1-4 connected with the above-described connector rings and side connector bars to form a floating solar panel array 500. The support modules are preferably spaced in accordance with ambient wave conditions of the body of water in which the installation will be deployed. Thus, the sizing and weight distribution of each module, and the spacing of modules relative to one another, can be tailored to minimize roll, pitch, yaw, heave, surge and sway under the wave conditions most likely to be encountered in the particular environment of use.

As will be appreciated by those with skill in the art, a number of suitable materials may be employed for the tubing and flotation elements of the support structure of the present invention, including fibre glass, PVC, composite material, metal, and so forth. The various components need not be fabricated from the same material, and some combination of plastic, composite, and/or metal may be preferable. The flotation element, e.g., a pontoon, is preferably sealed and may be left either with an unfilled void or it may be filled with polyethylene foam, polystyrene foam, or the like.

The above disclosure is sufficient to enable one of ordinary skill in the art to practice the invention, and provides the best mode of practicing the invention presently contemplated by the inventor. While there is provided herein a full and complete disclosure of the preferred embodiments of this invention, it is not desired to limit the invention to the exact construction, dimensional relationships, and operation shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Therefore, the above description and illustrations should not be construed as limiting the scope of the invention, which is defined by the appended claims.

What is claimed as invention is:

1. A floating support structure for a solar panel array, comprising:
first and second elongate flotation elements having front and rear ends;
connector tubes extending longitudinally from said front and rear ends of said elongate flotation elements, each of said connector tubes having a distal end;
front and rear connector rings disposed on said end of each of said connector tubes;
at least two upright supports having upper and lower ends, one each of said upright supports disposed proximate said first and second flotation elements;
panel frame tube mounting means disposed at the upper end of each of said upright support;
a solar panel frame tube mounted on said panel frame tube mounting means and disposed generally between said flotation elements, and journalled at its ends in said panel frame tube mounting means; and
one or more rails attached to said solar panel frame tube for mounting a solar panel.

2. The apparatus of claim 1, further including at least one transverse tube disposed between and connected to each of said upright supports.

3. The apparatus of claim 1, wherein said front connector rings are oriented generally perpendicular to said rear connector rings.

4. The apparatus of claim 1, wherein at least two of said front and rear connector rings include a hinge element that allows the rings to capture rings in an adjacent floating support structure.

5. The apparatus of claim 1, wherein said connector rings having a hinge element are carabineers.

6. The apparatus of claim 5, wherein at least two of said connector rings are rigid.

7. The apparatus of claim 1, wherein said upright supports are affixed at their lower ends to said connector tubes longitudinal extensions or to the flotation element, and which angle inwardly toward one another to join or substantially join at their respective upper ends,

8. The apparatus of claim 1, further including at least one side connector ring disposed along the length of each of said flotation elements or said connector tubes.

9. The apparatus of claim 1, further including side connection means to connect the sides of adjoining support structures.

10. The apparatus of claim 1, wherein said side connection means is a side connection bar, comprising a tube or bar having carbineer elements disposed on each end.

11. The apparatus of claim 1, wherein said upright supports comprise tubes angling toward one another at their respective upper ends, and wherein said panel frame tube mounting means comprises spaced apart plates affixed to said upper ends, each of said plates including a hole through which the end of said solar panel frame tube is journalled.

12. The apparatus of claim 11, wherein said solar panel frame tube is circular in cross section and is rotatable at its journalled ends.

13. The apparatus of claim 12, further including adjustment/locking means for permitting the selective release, rotation, and re-locking of said solar panel frame tube.

14. The apparatus of claim 13, wherein said adjustment/locking means is a pawl and ratchet.

15. A solar panel array, comprising a plurality of floating support structures for a solar panel array as described in claim 1, each of said floating support structures joined to at least one adjacent floating support structure at a front connector or rear connector.

16. The array of claim 15, further including at least one side connector disposed between side-by-side floating support structures and connecting at least one floating support structure to at least one other floating support structure.
